(19) United States
(12) Patent Application Publication
(10) Pub. No.: US 2006/0081332 A1
(43) Pub. Date: Apr. 20, 2006

(54) Laser induced thermal imaging (LITI) apparatus

(76) Inventors: Tae-Min Kang, Suwon-si (KR); Hye-Dong Kim, Suwon-si (KR); Myung-Won Song, Suwon-si (KR); Jae-Ho Lee, Suwon-si (KR)

Correspondence Address: Robert E. Bushnell, Suite 300, 1522 K Street, N.W., Washington, DC, 20005, US

(21) Appl. No.: 11/247,279

(22) Filed: Oct. 12, 2005

(30) Foreign Application Priority Data
Oct. 20, 2004 (KR) 2004-84150

(51) Int. Cl. B29C 65/00; B32B 37/00

(52) U.S. Cl. 156/285; 156/379.6; 156/391; 156/382

(57) ABSTRACT

Provided are a laser induced thermal imaging (LITI) apparatus, a laminator, and an LITI method using the apparatus. The LITI apparatus includes a chuck having at least one first lower ventilation hole for attracting a lower substrate toward the chuck. A cap is disposed on the chuck. The cap fixes an upper substrate and includes at least one first upper ventilation hole for pressurizing the upper substrate so that the upper substrate is closely adhered to the lower substrate. A laser irradiation system for irradiating a laser beam is disposed over the upper substrate adhered to the lower substrate. In this construction, the upper substrate can be laminated on the lower substrate.

### CLAIM OF PRIORITY

This application makes reference to, incorporates the same herein, and claims all benefits accruing under 35 U.S.C. § 119 from an application for LASER INDUCED THERMAL IMAGING APPARATUS, LAMINATOR, AND LASER INDUCED THERMAL IMAGING METHOD USING THE APPARATUS earlier filed in the Korean Intellectual Property Office on the 20 of Oct., 2004 and there duly assigned Serial No. 2004-84150.

### BACKGROUND OF THE INVENTION

1. Field of the Invention

The present invention relates to a Laser Induced Thermal Imaging (LITI) apparatus and, more particularly, to an LITI apparatus including a laminator and an LITI method using the apparatus.

2. Description of the Related Art

In general, a Laser Induced Thermal Imaging (LITI) method requires at least a laser, an acceptor substrate, and a donor film. The donor film includes a base film, a Light-to-Heat Conversion (LTHC) layer, and a transfer layer. The donor film is laminated on the acceptor substrate such that the transfer layer faces the acceptor substrate, and laser beams are irradiated onto the base film. The beams irradiated onto the base film are absorbed into the LTHC layer and converted into thermal energy, and the transfer layer is transferred onto the acceptor substrate due to the thermal energy. As a result, a transfer layer pattern is formed on the acceptor substrate. Examples of the above-described LITI method are disclosed in U.S. Pat. No. 5,998,085, U.S. Pat No. 6,214,520, and U.S. Pat. No. 6,114,088.

The lamination of the donor film on the acceptor substrate is performed by disposing the donor film on the acceptor substrate and applying pressure to the donor film with a roller. However, to obtain a uniformly laminated resultant structure, it is necessary to use a roller of great precision and to uniformly apply pressure with the roller. Also, the roller must be precisely controlled to synchronize the transfer of the roller with the rotation of the roller. Furthermore, it is difficult for a complicated and large-sized roller system to be attached to an LITI apparatus.

### SUMMARY OF THE INVENTION

The present invention, therefore, provides a Laser Induced Thermal Imaging (LITI) apparatus, which can perform a lamination process without using a roller.

In an exemplary embodiment of the present invention, an LITI apparatus includes a chuck having at least one first lower ventilation hole for attracting a lower substrate toward the chuck. A cap is disposed on the chuck. The cap fixes an upper substrate and includes at least one first upper ventilation hole for pressurizing the upper substrate to adhere the upper substrate to the lower substrate. A laser irradiation system is disposed on the upper substrate adhered to the lower substrate. The laser irradiation system is used to irradiate a laser beam onto the upper substrate. The upper substrate can be laminated to the lower substrate.

The first upper ventilation hole can be disposed in a central portion of the cap. A failure caused by bubbles can be suppressed during the lamination process.

The chuck can further include at least one second lower ventilation hole, which is disposed around the lower substrate and enables the adhesion of the upper substrate to the lower substrate or the detachment of the upper substrate from the lower substrate. Thus, the upper substrate can be further adhered to the lower substrate. After irradiating the laser beam, the upper substrate can be easily detached from the lower substrate.

The cap can further include a second upper ventilation hole for attracting the upper substrate toward the cap. Because a transfer layer of the upper substrate can be out of contact with the lower substrate, it can be freed from damage caused by contact.

The LITI apparatus can further include a stage for fixing the chuck, and the stage can include a lamination region and a laser irradiation region. The cap can be disposed over the lamination region, and the laser irradiation system can be disposed over the laser irradiation region. The stage can include a chuck guide for moving the chuck in an X-axis direction. The chuck can reciprocate between the lamination region and the laser irradiation region along the chuck guide.

In another exemplary embodiment of the present invention, a laminator includes a chuck having at least one first lower ventilation hole for attracting a lower substrate toward the chuck. A cap is disposed on the chuck. The cap fixes an upper substrate and includes at least one first upper ventilation hole for pressurizing the upper substrate to adhere the upper substrate to the lower substrate.

In still another exemplary embodiment of the present invention, an LITI method includes disposing a lower substrate on a chuck and disposing an upper substrate including at least a Light-to-Heat Conversion (LTHC) layer and a transfer layer such that the transfer layer faces the lower substrate. An air pressure in a space above the upper substrate is raised to a higher pressure than an air pressure in a space below the upper substrate so that the upper substrate is closely adhered to the lower substrate. A laser beam is irradiated onto the upper substrate adhered to the lower substrate, thereby transferring at least one portion of the transfer layer onto the lower substrate.

The chuck can include at least one first lower ventilation hole, and the chuck can fix the lower substrate by forming a vacuum through the first lower ventilation hole.

The upper substrate can be fixed to a cap including at least one first upper ventilation hole, and the air pressure in the space above the upper substrate can be raised to a higher pressure than the air pressure in the space below the upper substrate by injecting a compressed gas through the first upper ventilation hole.

The chuck can further include at least one second lower ventilation hole, which is disposed around the lower substrate. Before or after injecting the compressed gas through the first upper ventilation hole, the LITI method can further include closely attracting the upper substrate toward the lower substrate by forming a vacuum through the second lower ventilation hole.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a perspective view of a Laser Induced Thermal Imaging (LITI) apparatus 100 according to an exemplary embodiment of the present invention;

FIG. 2 is a cross-sectional view taken along line I-I′ of FIG. 1;

FIGS. 3A, 3B, 3C, 3D, 3E and 3F are cross-sectional views taken along line I-I′ of FIG. 1, which illustrate an LITI method according to an exemplary embodiment of the present invention;

FIG. 4A is a magnified cross-sectional view of a portion of FIG. 3A;

FIG. 4B is a magnified cross-sectional view of another portion of FIG. 3A; and

FIG. 5 is a magnified cross-sectional view of a portion of FIG. 3F.

### DETAILED DESCRIPTION OF THE INVENTION

The present invention will now be described more fully hereinafter with reference to the accompanying drawings, in which exemplary embodiments of the invention are shown. This invention can, however, be embodied in different forms and should not be construed as being limited to the embodiments set forth herein. It will also be understood that when a layer is referred to as being “on” another layer or substrate, it can be directly on the other layer or substrate or intervening layers can also be present. The same reference numerals are used to denote the same elements throughout the specification.

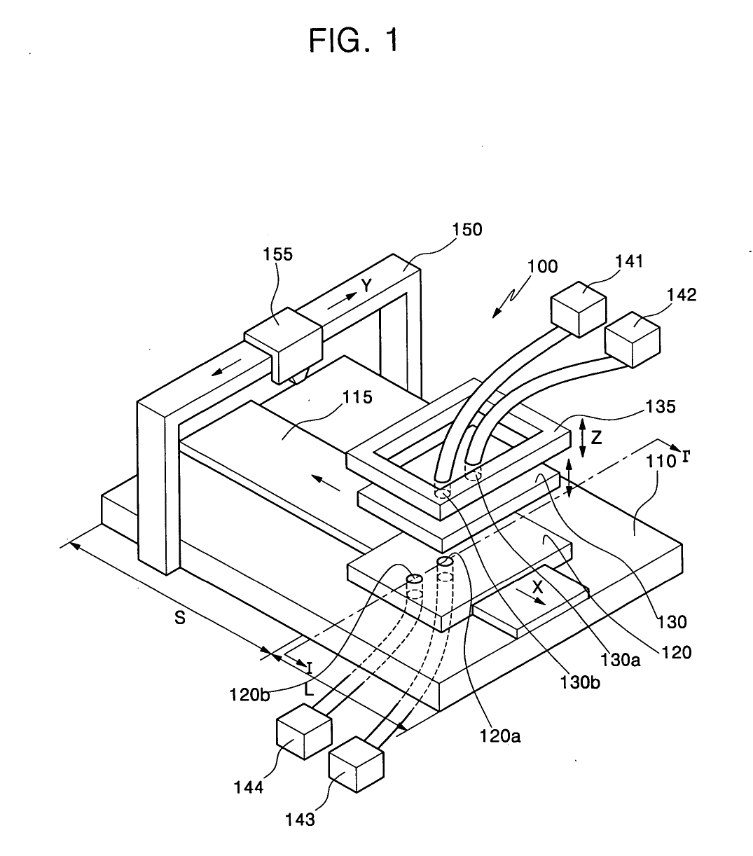

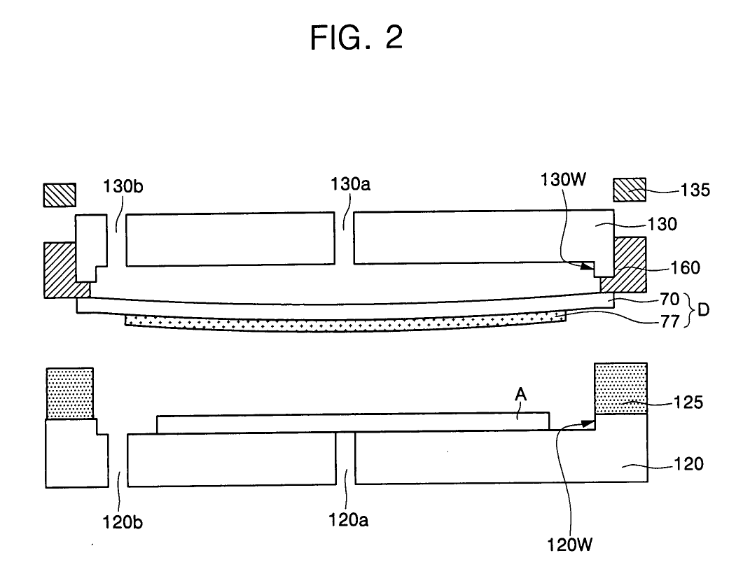

FIG. 1 is a perspective view of a Laser Induced Thermal Imaging (LITI) apparatus 100 according to an exemplary embodiment of the present invention, and FIG. 2 is a cross-sectional view taken along line I-I′ of FIG. 1.

Referring to FIGS. 1 and 2, the LITI apparatus 100 includes a stage 110 having a lamination region L and a laser irradiation region S. The stage 110 fixes a chuck 120 and includes a chuck guide 115 for moving the chuck 120 in an X-axis direction. Thus, the chuck 120 can reciprocate between the lamination region L and the laser irradiation region S along the chuck guide 115.

The chuck 120 includes at least one first lower ventilation hole 120a for attracting a lower substrate A toward the chuck 120. Also, the chuck 120 can further include at least one second lower ventilation hole 120b disposed around the lower substrate A. The first and second lower ventilation holes 120a and 120b are respectively connected to a first lower vacuum pump 143 and a second lower vacuum pump 144. The chuck 120 can include a well 120w. In this case, the first and second lower ventilation holes 120a and 120b are disposed in a bottom surface of the well 120w, and the lower substrate A is disposed inside the well 120w.

A cap 130 is disposed over the lamination region L. When the chuck 120 is disposed on the lamination region L, the cap 130 is disposed on the chuck 120. The cap 130 fixes an upper substrate D. When the upper substrate D is supported by a frame 160, the cap 130 fixes the frame 160 so that the upper substrate D can be fixed.

The cap 130 includes at least one first upper ventilation hole 130a for pressurizing the upper substrate D such that the upper substrate D is closely adhered to the lower substrate A. Preferably, the first upper ventilation hole 130a is disposed in a central portion of the cap 130. The second lower ventilation hole 120b disposed in the chuck 120 can also serve to closely adhere the upper substrate D to the lower substrate A. However, after the upper substrate D is closely adhered to the lower substrate A, the second lower ventilation hole 120b can make it easier to detach the upper substrate D from the lower substrate A.

Also, the cap 130 can further include a second upper ventilation hole 130b for attracting the upper substrate D toward the cap 130. The first and second upper ventilation holes 130a and 130b are respectively connected to a first upper vacuum pump 142 and a second upper vacuum pump 141.

The cap 130 can include a well 130w. In this case, the first and second upper ventilation holes 130a and 130b are disposed in a bottom surface of the well 130w, and the upper substrate D is out of contact with the bottom surface of the well 130w. The cap 130 can move in a Z-axis namely, an up-down direction. Accordingly, the cap 130 can be attached to or detached from the chuck 120.

A frame pressurizing unit 135 can be disposed around and apart from the cap 130. The frame pressurizing unit 135 is used to closely attach the frame 160 to the chuck 120.

An elastic member 125 can be disposed on an outer portion of the chuck 120. When the cap 130 and/or the frame 160 are closely attached to the chuck 120, the elastic member 125 can hermetically seal a space formed between the cap 130 and the chuck 120.

A laser irradiation system 155 is disposed over the laser irradiation region S. The laser irradiation system 155 is mounted on a laser guide bar 150. The laser irradiation system 155 can move along the laser guide bar 150 in a Y-axis direction. When the chuck 120 is disposed in the laser irradiation region S, the laser irradiation system 155 is disposed over the chuck 120.

In the present embodiment, the LITI apparatus 100 is exemplarily described. However, the chuck 120 and the cap 130 can constitute an additional laminator.

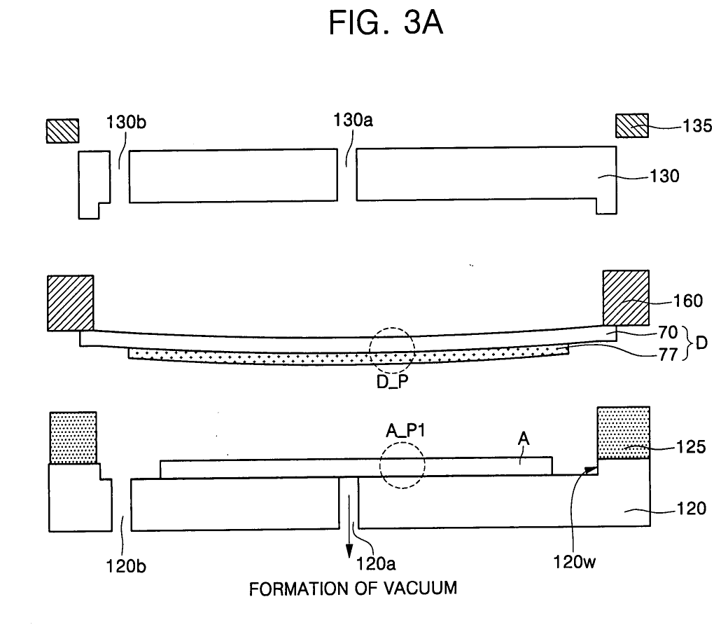

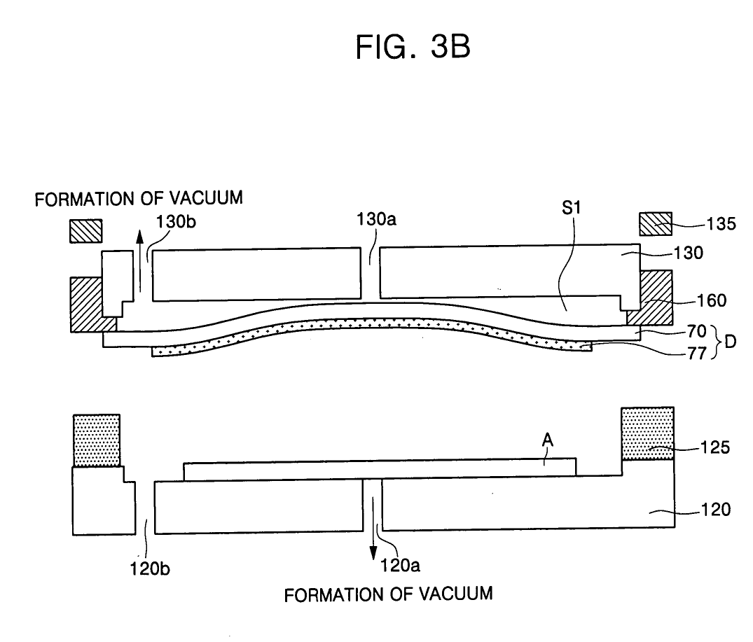

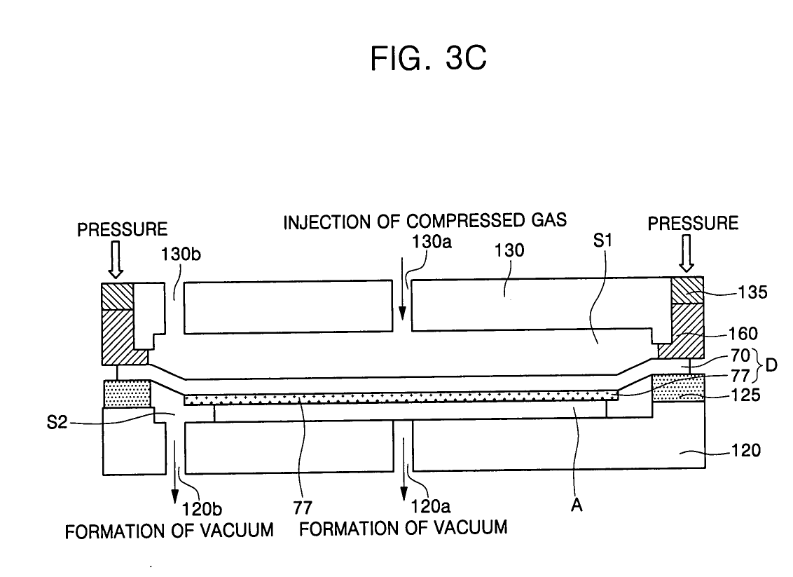

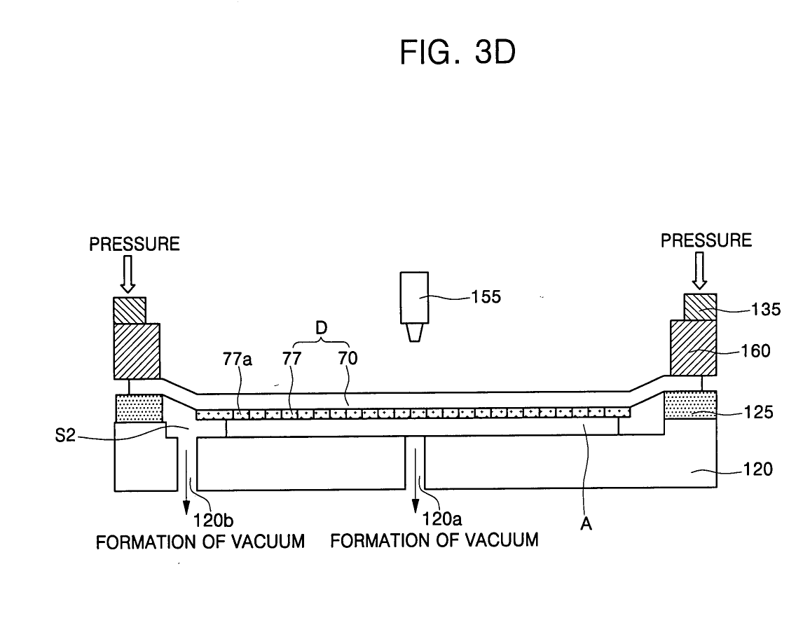

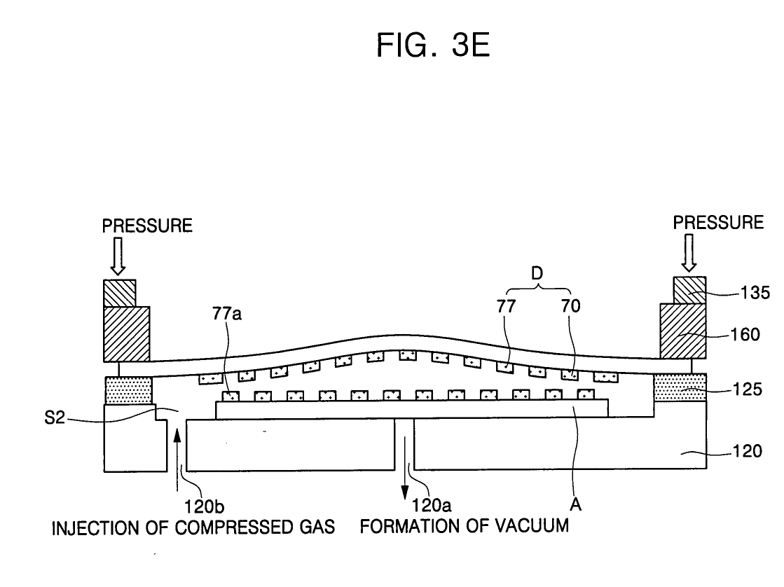

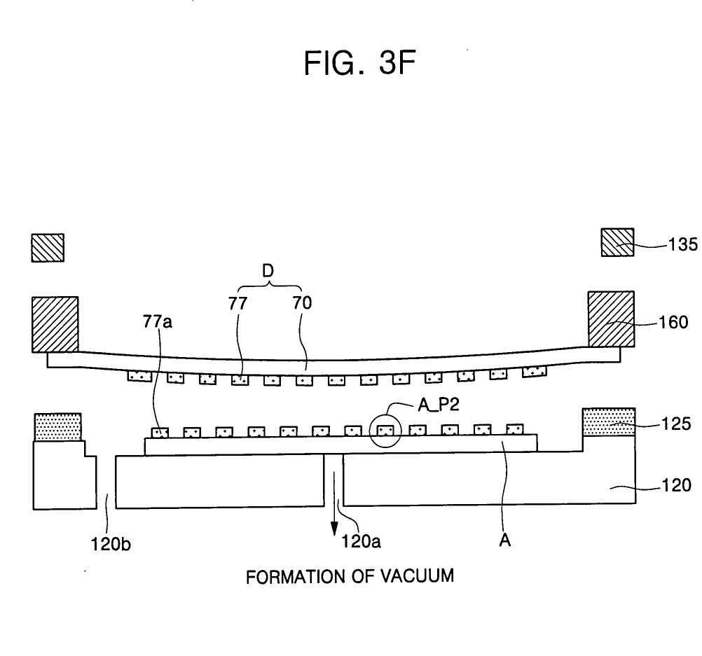

FIGS. 3A, 3B, 3C, 3D, 3E and 3F are cross-sectional views taken along line I-I′ of FIG. 1, which illustrate an LITI method using the above-described LITI apparatus 100.

Referring to FIG. 3A, a lower substrate A is disposed on a chuck 120. When the chuck 120 includes a well 120w, the lower substrate A is disposed on a bottom surface of the well 120w.

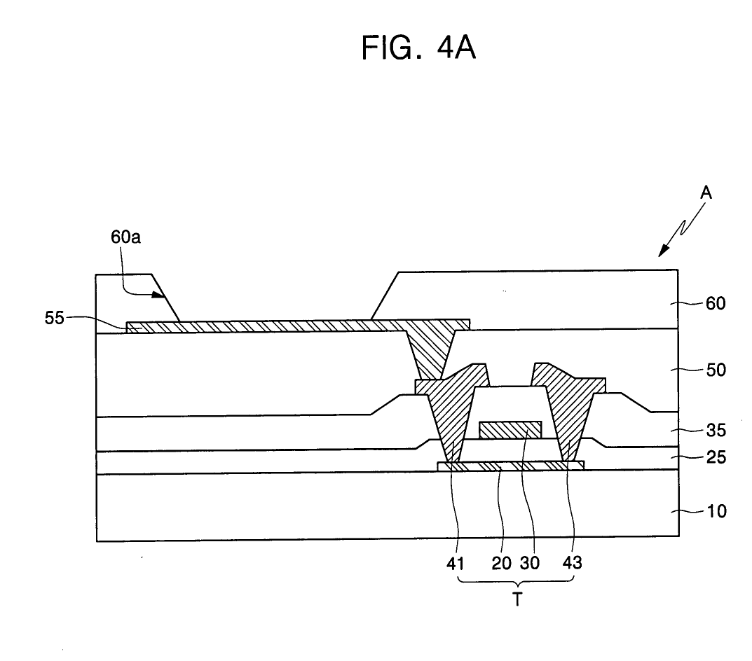

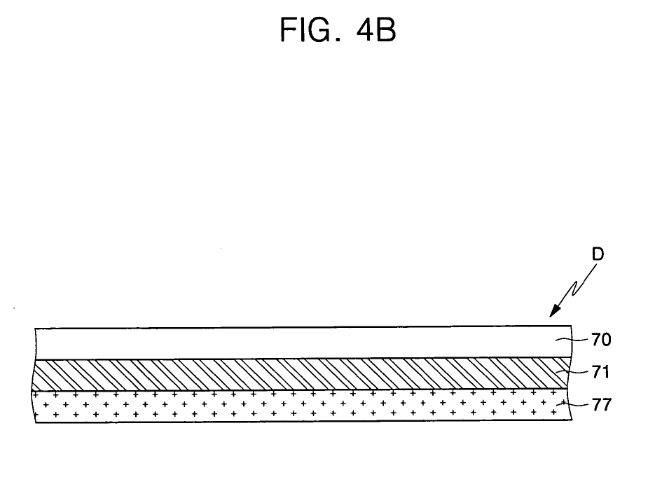

FIG. 4A is a magnified cross-sectional view of a portion A_P1 of the lower substrate A. In this case, the lower substrate A is a substrate for an Organic Light Emitting Device (OLED). Referring to FIG. 4A, a semiconductor layer 20 is disposed on a predetermined region of a substrate 10. The semiconductor layer 20 can be an amorphous silicon (a-Si) layer or a polysilicon (poly-Si) layer obtained by crystallizing the a-Si layer. A gate insulating layer 25 is disposed on the semiconductor layer 20. A gate electrode 30 is disposed on the gate insulating layer 25 such that it overlaps the semiconductor layer 20. A first interlayer insulating layer 35 is disposed on the gate electrode 30 to cover the semiconductor layer 20 and the gate electrode 30. A drain electrode 41 and a source electrode 43 are disposed on the first interlayer insulating layer 35. The drain and source electrodes 41 and 43 are respectively connected to both edge portions of the semiconductor layer 20, through the first interlayer insulating layer 35 and the gate insulating layer 25. The semiconductor layer 20, the gate electrode 30, and the drain and source electrodes 41 and 43 constitute a thin-film transistor T. A second interlayer insulating layer 50 covers the source and drain electrodes 41 and 43. The second interlayer insulating layer 50 can include a passivation layer for protecting the thin-film transistor T and/or a planarization layer for reducing a step caused by the thin-film transistor T. A pixel electrode 55 is disposed on the second interlayer insulating layer 50. The pixel electrode 55 is connected to the drain electrode 41 through the second interlayer insulating layer 50. The pixel electrode 55 can be, for example, an Indium Tin Oxide (ITO) layer or an Indium Zinc Oxide (IZO) layer. A pixel defining layer 60 can be disposed on the pixel electrode 55. The pixel defining layer 60 includes an opening 60a, which exposes a portion of the pixel electrode 55.

Referring again to FIG. 3A, after the lower substrate A is disposed on the chuck 120, a first lower vacuum pump (143 of FIG. 1), which is connected to a first lower ventilation hole 120a disposed in the bottom surface of the well 120w, is operated. Thus, a vacuum is obtained in a space between the lower substrate A and the chuck 120. As a result, the lower substrate A is closely attracted toward the chuck 120. Throughout the specification, “vacuum” refers to a lower pressure than an external pressure.

Thereafter, an upper substrate D is conveyed to a space between the chuck 120 and the cap 130 disposed over the chuck 120.

FIG. 4B is a magnified cross-sectional view of a portion D_P of the upper substrate D. Referring to FIG. 4B, the upper substrate D includes a base substrate 70 and a Light-to-Heat Conversion (LTHC) layer 71 and a transfer layer 77, which are sequentially stacked on the base substrate 70. The base substrate 70 can be a substrate formed of a transparent polymeric organic material, such as PolyEthyleneTerephthalate (PET). The LTHC layer 71, which converts incident light into heat, can contain a light absorption material, such as aluminum oxide, aluminum sulfide, carbon black, black lead, or an infrared dye. When the lower substrate A is a substrate for the OLED, the transfer layer 77 can be an organic emission layer. Also, the transfer layer 77 can further include one layer selected from the group consisting of an organic hole injection layer, an organic hole transport layer, an organic hole blocking layer, an organic electron transport layer, and an organic electron injection layer.

Referring again to FIG. 3A, the upper substrate D is disposed such that the transfer layer 77 faces the lower substrate A. When the upper substrate D is conveyed, it can be supported by a frame 160. However, even if the upper substrate D is supported by the frame 160, its central portion can sag. This is because the base substrate 70 of the upper substrate D is a flexible substrate formed of a polymeric material as described above.

Referring to FIG. 3B, the cap 130 moves downward in a Z-axis direction and combines with the frame 160. As a result, the frame 160 is fixed to the cap 130. In addition, the upper substrate D supported by the frame 160 also is fixed to the cap 130. Thus, a first isolated space S1 is formed between the upper substrate D and the cap 130.

Thereafter, a second upper vacuum pump (141 of FIG. 1), which is connected to a second upper ventilation hole 130b of the cap 130, is operated. Thus, a vacuum is obtained in the first isolated space S1, and the upper substrate D, whose central portion sags, is closely attracted toward the cap 130. As a result, since the transfer layer 77 of the upper substrate D is out of contact with the lower substrate A, it can be free from damage caused by the contact.

Referring to FIG. 3C, the cap 130, which fixes the frame 160, further moves downward in a Z-axis direction and is closely adhered to the chuck 120. After that, a predetermined pressure can be applied to the cap 130. Also, a frame pressurizing unit 135 moves downward such that it is closely adhered to the frame 160 fixed to the cap 130 and pressurizes the frame 160. Thus, the cap 130 and the frame 160 can be further adhered to the chuck 120. In this case, an elastic member 125 disposed in an outer portion of the chuck 120 can be compressed. A second isolated space S2 is formed between the chuck 120 and the upper substrate D, which are adhered to each other. The compressed elastic member 125 can hermetically seal the second isolated space S2.

Subsequently, a compressed gas is injected through the first upper ventilation hole 130a of the cap 130. As a result, a pressure in the first isolated space S1 can rise. The raised pressure of the first isolated space S 1 enables the upper substrate D to be closely adhered to the lower substrate A. Preferably, the first upper ventilation hole 130a is disposed in a central portion of the cap 130. Thus, a central portion of the upper substrate D is firstly adhered to the lower substrate A, and then an outer portion of the upper substrate D can be adhered to the lower substrate A. In conclusion, the upper substrate D can be reliably laminated on the lower substrate A without generating bubbles. The compressed gas is injected through the first upper ventilation hole 130a at a higher pressure than the internal pressure of the second isolated space S2. In other words, the upper substrate D is closely adhered to the lower substrate A due to an air pressure difference between a space above the upper substrate D (i.e., the first isolated space S1) and a space below the upper substrate D (i.e., the second isolated space S2).

When the chuck 120 includes the second lower ventilation hole 120b, the second lower vacuum pump (144 of FIG. 1), which is connected to the second lower ventilation hole 120b, is operated so that a vacuum is obtained in the second isolated space S2. As a result, the upper substrate D can be further adhered to the lower substrate A, and a pressure at which the compressed gas is injected into the first upper ventilation hole 130a can be lowered. The elastic member 125 can hermetically seal the second isolated space S2 so as to keep the vacuum in the second isolated space S2. The injection of the compressed gas through the first upper ventilation hole 130a and the obtaining of a vacuum in the second isolated space S2 using the second lower ventilation hole 120b can be performed in reverse order or at the same time.

Referring to FIG. 3D, while the cap 130 is moving upward in the Z-axis direction, it is detached from the frame 160. However, the frame pressurizing unit 135 still pressurizes the frame 160 to the chuck 120, so that the second isolated space S2, which is sealed, maintains a vacuum due to the second lower ventilation hole 120b. Accordingly, the upper substrate D easily remains closely adhered to the lower substrate A.

Thereafter, the chuck 120 including the laminated upper and lower substrates D and A moves along the chuck guide (115 of FIG. 1) in a X-axis direction so that it is disposed below the laser irradiation system 155. While the laser irradiation system 155 moves along the laser guide bar (150 of FIG. 1) in a Y-axis direction, it irradiates laser beams onto the upper substrate D. Then, the chuck 120 moves by a pitch along the chuck guide 115 in a X-axis direction in the laser irradiation region (S of FIG. 1), and the laser irradiation system 155 moves along the laser guide bar 150 in a Y-axis direction and simultaneously irradiates laser beams onto the upper substrate D. This process is repeated until laser beams have been irradiated onto the entire upper substrate D. In this case, in the laser irradiated region of the upper substrate D, the LTHC layer (71 of FIG. 4B) absorbs the laser beams and generates heat, resulting in the adhesion between the transfer layer 77 disposed under the LTHC layer 71 and the LTHC layer 71 being degraded due to the heat. As a result, the transfer layer 77 is transferred onto the lower substrate A. That is, a transfer layer pattern 77a is formed on the lower substrate A.

Referring to FIG. 3E, while the frame pressurizing unit 135 is still pressurizing the frame 160 to the chuck 120, a compressed gas is injected through the second lower ventilation hole 120b. As a result, a pressure in the second isolated space S2 rises, and the upper substrate D can be detached from the lower substrate A.

Referring to FIG. 3F, when the upper substrate D is completely detached from the lower substrate A, the frame pressurizing unit 135 stops pressurizing the frame 160 and moves upward. Similarly, the frame 160 also moves upward. As a result, the transfer layer pattern 77a disposed on the lower substrate A is exposed.

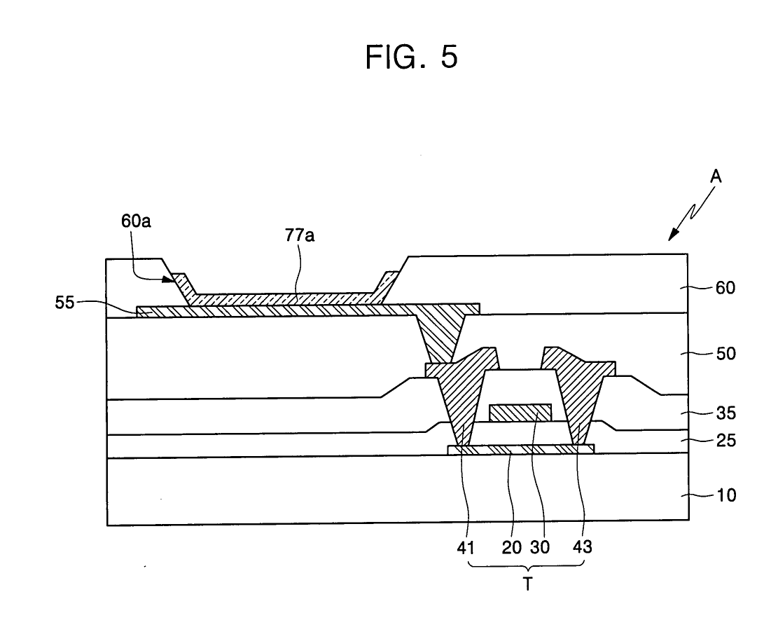

FIG. 5 is a magnified cross-sectional view of a portion A_P2 of the lower substrate A including the transfer layer pattern 77a. Referring to FIG. 5, the transfer layer pattern 77a is disposed on the pixel electrode 55 exposed in the opening 60a for the OLED, as described with reference to FIG. 4A. The transfer layer pattern 77a can be an organic emission layer. Also, the transfer layer pattern 77a can further include at least one layer selected from the group consisting of a hole injection layer, a hole transport layer, a hole blocking layer, an electron transport layer, and an electron injection layer.

According to the present invention as described above, an upper substrate can be reliably laminated on a lower substrate without using a roller. In addition, a lamination process and a laser irradiation process can be performed in the same apparatus.

Although the present invention has been described with reference to certain exemplary embodiments thereof, it will be understood by those skilled in the art that a variety of modifications and variations can be made to the present invention without departing from the spirit or scope of the present invention defined by the appended claims.

What is claimed is:

1. A Laser Induced Thermal Imaging (LITI) apparatus, comprising:
a chuck having at least one first lower ventilation hole adapted to attract a lower substrate toward the chuck;
a cap arranged on the chuck and adapted to fix an upper substrate, the cap including at least one first upper ventilation hole adapted to pressurize the upper substrate to adhere the upper substrate to the lower substrate; and
a laser irradiation system adapted to irradiate a laser beam on the upper substrate adhered to the lower substrate.

2. The apparatus according to claim 1, wherein the first upper ventilation hole is arranged in a central portion of the cap.

3. The apparatus according to claim 1, wherein the chuck further comprises at least one second lower ventilation hole arranged around the lower substrate and adapted to adhere the upper substrate to the lower substrate or to detach the upper substrate from the lower substrate.

4. The apparatus according to claim 1, wherein the cap further comprises a second upper ventilation hole adapted to attract the upper substrate toward the cap.

5. The apparatus according to claim 1, wherein the cap is adapted to move in a Y-axis direction.

6. The apparatus according to claim 1, further comprising a frame adapted to support the upper substrate, wherein the cap is adapted to fix the frame.

7. The apparatus according to claim 6, further comprising a pressurizing unit adapted to pressurize the frame to the chuck.

8. The apparatus according to claim 1, further comprising an elastic member arranged in an outer portion of the chuck.

9. The apparatus according to claim 1, further comprising a stage adapted to fix the chuck.

10. The apparatus according to claim 9, wherein:
the stage includes a lamination region and a laser irradiation region;
the cap is arranged over the lamination region; and
the laser irradiation system is arranged over the laser irradiation region.

11. The apparatus according to claim 9, wherein the stage comprises a chuck guide adapted to move the chuck in an X-axis direction.

12. The apparatus according to claim 11, wherein:
the stage comprises a lamination region and a laser irradiation region;
the cap is arranged over the lamination region;
the laser irradiation system is arranged over the laser irradiation region; and
the chuck is adapted to reciprocate between the lamination region and the laser irradiation region along the chuck guide.

13. A Laser Induced Thermal Imaging (LITI) apparatus, comprising:
a cap adapted to an upper substrate, the cap including at least one first upper ventilation hole adapted to pressurize the upper substrate to adhere the upper substrate to a lower substrate;
a chuck including at least one first lower ventilation hole adapted to attract the lower substrate toward the chuck and at least one second lower ventilation hole adapted to adhere the upper substrate to the lower substrate; and
a laser irradiation system adapted to irradiate a laser beam onto the upper substrate adhered to the lower substrate.

14. The apparatus according to claim 13, wherein the first upper ventilation hole is arranged in a central portion of the cap.

15. The apparatus according to claim 13, wherein the cap further comprises a second upper ventilation hole adapted to attract the upper substrate toward the cap.

16. The apparatus according to claim 13, further comprising a frame adapted to support the upper substrate, wherein the cap is adapted to fix the frame.

17. The apparatus according to claim 16, further comprising a pressurizing unit adapted to pressurize the frame to the chuck.

18. The apparatus according to claim 13, further comprising an elastic member arranged in an outer portion of the chuck.

19. The apparatus according to claim 13, wherein the cap is adapted to move in a Y-axis direction.

20. A laminator, comprising:
a chuck having at least one first lower ventilation hole adapted to attract a lower substrate toward the chuck; and
a cap arranged on the chuck and adapted to fix an upper substrate, the cap including at least one first upper ventilation hole adapted to pressurize the upper substrate to adhere the upper substrate to the lower substrate.

21. The laminator according to claim 20, wherein the first upper ventilation hole is arranged in a central portion of the cap.

22. The laminator according to claim 20, wherein the cap further comprises a second upper ventilation hole adapted to attract the upper substrate toward the cap.

23. The laminator according to claim 20, further comprising a frame adapted to support the upper substrate, wherein the cap is adapted to fix the frame.

24. The laminator according to claim 20, further comprising an elastic member arranged in an outer portion of the chuck.

25. A Laser Induced Thermal Imaging (LITI) method, comprising:
arranging a lower substrate on a chuck;
arranging an upper substrate including at least a Light-to-Heat Conversion (LTHC) layer and a transfer layer such that the transfer layer faces the lower substrate;
closely adhering the upper substrate to the lower substrate by raising an air pressure in a space above the upper substrate to a pressure higher than an air pressure in a space below the upper substrate; and
transferring at least one portion of the transfer layer onto the lower substrate by irradiating a laser beam on the upper substrate adhered to the lower substrate.

26. The method according to claim 25, further comprising providing the chuck with at least one first lower ventilation hole; wherein the chuck closely attracts the lower substrate by forming a vacuum through the first lower ventilation hole.

27. The method according to claim 25, further comprising fixing the upper substrate to a cap including at least one first upper ventilation hole; and
raising the air pressure in a space above the upper substrate to a pressure higher than the air pressure in a space below the upper substrate comprises injecting a compressed gas through the first upper ventilation hole.

28. The method according to claim 27, wherein the cap further includes a second upper ventilation hole, and further comprising attracting the upper substrate closely to the cap by forming a vacuum through the second upper ventilation hole before injecting the compressed gas through the first upper ventilation hole.

29. The method according to claim 27, further comprising:
providing the chuck with at least one second lower ventilation hole arranged around the lower substrate, and
attracting the upper substrate closely to the lower substrate by forming a vacuum through the second lower ventilation hole before or after injecting the compressed gas through the first upper ventilation hole.

30. The method according to claim 25, further comprising:
providing the chuck with at least one second lower ventilation hole arranged around the lower substrate, and
detaching the upper substrate from the lower substrate by injecting a compressed gas through the second lower ventilation hole after transferring the transfer layer.
